(19) United States
(12) Patent Application Publication
(10) Pub. No.: US 2010/0126961 A1
(43) Pub. Date: May 27, 2010

(54) Polysilicon Planarization Solution for Planarizing Low Temperature Poly-Silicon Thin Film Panels

(76) Inventors: Sang In Kim, Giheung-gu Yongin City (KR); Seong Jin Hong, Chungcheongbuk-do (KR)

Correspondence Address: Mallinckrodt Inc., 675 McDonnell Boulevard, HAZELWOOD, MO, 63042, US

(21) Appl. No.: 12/596,921

(22) PCT Filed: Feb. 19, 2008
(86) PCT No.: PCT/US2008/002169

§ 371 Date: Oct. 21, 2009

Related U.S. Application Data
(60) Provisional application No. 60/914,105, filed on Apr. 26, 2007.

(51) Int. Cl. C23F 1/32; C09K 13/02

(52) U.S. Cl. 216/38; 252/79.1; 252/79.5

(57) ABSTRACT

A highly aqueous, strongly basic planarizing solution and a process for its use to reducing or essentially eliminating protrusions or projections extending generally upwardly from a generally planar surface of polysilicon film produced by Low Temperature Poly Si (LTPS) annealing a film of amorphous silicon deposited on a substrate; the process including contacting the surface of the generally planar polysilicon film with the highly aqueous, strongly basic solution for a time sufficient to selectively etch the protrusions or projections from the surface of the generally planar polysilicon film without any significant etching of the generally planar polysilicon film, said highly aqueous, strongly basic solution being a solution having a pH of 12 or higher and comprising water, at least one strong base, and at least one etch rate control agent.

### FIELD OF THE INVENTION

This invention relates to a highly aqueous, strongly basic planarizing solution for planarizing polysilicon layers employed in the production of liquid crystal displays (LCDs), Micro Electro Mechanical Systems (MEMS) and Solar Cell substrates and to the use of such solution for planarizing the polysilicon layer produced in the production of LCDs and other poly Si substates devices. The highly aqueous, strongly basic planarizing solution selectively etches mountainous protrusion or projections extending upwardly from the surface of a generally planar polysilicon film produced by annealing amorphous silicon in a Low temperature poly Si (LTPS) process and to do so without any significant etching of the generally planar polysilicon film.

### BACKGROUND TO THE INVENTION

Recently, the need for poly Si devices is growing gradually because of its higher electrical performance, faster signal transmission and lower power consumption than amorphous Si devices. The major part of these poly Si adapting devices are LCDs (for mobile devices and TV), MEMS (for IT, BT sensors, metrics, modules) and Solar Cell substrate. In the past amorphous silicon thin film transistor liquid crystal displays (a-Si TFT-LCD) has been the primary device used in the market as an alternative to the previously employed cathode ray tube display (CRT-display). The reason for the development of the a-Si TFT-LCD was generally due to its lightness and thinness. However, as the field of information and data technology has continued to rapidly advance, the need for better resolution and transmittance requirements has become so crucial that many of the Si TFT-LCDs are unable to meet those more stringent requirements. In view of that the industry has developed a new technology to provide devices to meet these increased resolution and transmittance requirements. This new technology is known as low temperature poly-silicon thin film transistor (LTPS TFT) technology.

In the LTPS TFT technology the process generally comprises the following steps. First, an insulated substrate, that is generally a transparent glass or quartz, is provided. Second, a coating of amorphous silicon film is deposited on a major surface of the insulated substrate, such as by a Plasma Enhanced Chemical Vapor Deposition (PECVD) process. Third, there is performed an annealing process to re-crystallize and transform the amorphous silicon film to a polysilicon film. This annealing process is generally conducted in a chamber with an Eximer Laser Annealer (ELA) or Sequential Lateral Solidification (SLS). This polysilicon film forms a source area, a drain area and ,a channel area of the LTPS TFT. Next in the channel area a second deposition process, e.g., PECVD, is performed to form a silicon dioxide layer on the polysilicon film. Then a scan line and data line driving circuit area (plurality of driving circuits) and a display area (plurality of pixel units) are produced on the glass substrate. Typical process for the production of LTPS-TFT products are disclosed, for example, in the following U.S. Pre-Grant Application Publication Nos. 2004/0018649; 2005/0090045; 2005/0162373; 2005/0230753; 2006/0238470; and U.S. Pat. No. 6,846,707, the disclosures of which are all incorporated herein by reference thereto.

It has been discovered that in the process of forming the polysilicon film coating from the amorphous silicon by annealing there have been structural barriers and problems encountered. Among the problems is the formation of sharp mountain-shaped structures protruding or projecting upwardly from the generally planar poly-silicon film layer. The height difference and sharp shape of these of these upwardly protruding or projecting mountain-shaped structures has been reported to cause reliability failures due to leakage current and structure deformation when depositing oxide or nitride layers on the polysilicon surface. There is, therefore, a need to be able to reduce or eliminate these height differences of the polysilicon film layer without damaging or etching the surface of the polysilicon film surface or other areas covered by natural Si oxide (SiOₓ).

### SUMMARY OF THE INVENTION

In accordance with this invention there is provided highly aqueous, strongly basic, polysilicon planarizing solutions of water, at last one strong base and at least one etch rate control agent. The solutions may, and generally will, contain other optional components, such as for example, at least one oxidizer and at least one surfactant. A polysilicon film layer formed by annealing a film layer of amorphous silicon deposited on a substrate and having mountain shaped structures, protrusions or projections extending upwardly from the generally planar surface of the polysilicon film layer is contacted with such highly aqueous, strongly basic, polysilicon planarizing solutions to substantially reduce or eliminate those upwardly extending mountain shaped structures, protrusions or projections without any significant etching of generally planar polysilicon planar layer or any Si oxide layer on the generally planar polysilicon film. The highly aqueous, strong basic polysilicon planarizing solutions are those having water, a least one strong base and at least one etch control solvent, and optionally at least one oxidant and/or at least one surfactant. The highly aqueous, strongly basic polysilicon planarizing compositions of this invention will generally have a pH of 12 or more, generally a pH of from about 13.2 to about 14.5.

### DETAILED DESCRIPTION OF THE INVENTION AND PREFERRED EMBODIMENTS

The highly aqueous, strongly basic, polysilicon planarizing solutions of this invention comprise water, a strong base and an etch rate control agent, and optionally contain a surfactant and an oxidizer. The highly aqueous, strongly basic, polysilicon planarizing solutions will generally have a pH of 12 or greater, and preferably a pH of from about 13.2 to about 14.5. The invention is further directed to a process in which a polysilicon film layer formed by annealing a film layer of amorphous silicon on a substrate and having mountain shaped structures or protrusions or projections extending upwardly from the generally planar surface of the polysilicon film layer is contacted with such highly aqueous, strongly basic, polysilicon planarizing solutions to substantially reduce or eliminate those upwardly extending generally mountain shaped structures, protrusions or projections without any significant etching of the generally planar polysilicon film.

The highly aqueous, strongly basic, polysilicon planarizing solutions of this invention will generally have a pH of 12 or greater, generally a pH of from about pH 13.2 to 14.5, and more preferably a pH of from about 13.5 to about 14.4.

The highly aqueous, strongly basic, polysilicon planarizing solutions of this invention will have strong base present in an amount of from about 0.1 to about 10%, preferably from about 1.0 to about 6.0%, more preferably about 1.8% to about 3.2%, by weight of the planarizing solution.

The highly aqueous, strongly basic, polysilicon planarizing solutions will have present at least one strong base. The strong base is selected from a tetraalkylammonium hydroxide, choline, an alkali hydroxide such as sodium or potassium hydroxide, an alkaline earth metal hydroxide such as magnesium or calcium hydroxide, an alkali, alkaline earth or alkyl carbonate, an alkali, alkaline earth or alkyl acetate, an alkali, alkaline earth or alkyl alkoxide, an alkali, alkaline earth or alkyl cyanide, an alkali, alkaline earth or alkyl perchlorate, a mercapto compound, an alkyl phosphate, an alkyl arsenide, a Lewis Base which can easily accept proton ions, and mixtures thereof. The tetraalkylammonium hydroxide is the preferred base and any suitable tetraalkylammonium hydroxide of the formula

[(R)₄N⁺]ₚ[X]^{-q}

wherein each R is independently a substituted or unsubstituted alkyl, preferably alkyl or hydroxy alkyl of from 1 to 22, and more preferably 1 to 6, and still more preferably 1 to 4, carbon atoms; X=OH or a suitable salt anion, such as carbonate and the like; and p and q are equal and are integers of 1 to 3. Most preferably the tetraalkylammonium hydroxide is tetramethylammonium hydroxide (TMAH). If an alkali metal hydroxide is employed it is preferably NaOH or KOH.

The highly aqueous, strongly basic, polysilicon planarizing solutions of this invention will contain at least one etch rate control agent. Such etch rate control agents are alcohols or glycols. Any suitable alcohol or glycol etch rate control agent may be employed. Examples of such alcohol and glycols useful as etch rate control agent in the highly aqueous, strongly basic, polysilicon planarizing solutions of this invention include, but are not limited to: ethylene glycol, glycerol, ethyl carbitol, triethylene glycol and tetraethylene glycol and mixtures thereof. The at least one etch rate control agent will generally be present in the highly aqueous, strongly basic, polysilicon planarizing solutions in an amount of from about 0.1 to about 10%, preferably from about 0.5 to about 5%, and more preferably from about 0.5 to about 2%, by weight of the solution.

Water will be present in the highly aqueous, strongly basic, polysilicon planarizing solutions of this invention in an amount of from about 84.5 to about 99.8%, preferably from about 84.5 to about 97%, more preferably from about 90 to about 97%, by weight based on the weight of the planarizing solution.

The highly aqueous, strongly basic, polysilicon planarizing solutions of this invention may optionally, and generally will contain at least one oxidizer. Any suitable oxidizer may be employed. As examples of such oxidizer that may be employed in the highly aqueous, strongly basic, polysilicon planarizing solutions of this invention there may be mentioned permanganates, perchromates, persulfates, perchlorates, peroxides, ozone and other hyperoxidized materials, and mixtures thereof. Suitable oxidizers for use in the planarizing solutions of this invention include, but are not limited to: ammonium persulfate, ammonium perchlorate, ammonium permanganate, and ammonium perchromate. The oxidizer component, if employed in the solutions of this invention will generally be present in the highly aqueous, strongly basic, polysilicon planarizing solutions in an amount of from about 0.01 to about 0.5% by weight, preferably 0.05 to 0.3%, more preferably from about 0.1 to about 0.2%, based on the weight of the solution.

The highly aqueous, strongly basic, polysilicon planarizing solutions of this invention also optionally contains at least one surfactant. The surfactant, when present in the composition, may also act as an etch rate control agent. When a surfactant is present the amount of surfactant will generally be an amount of from about 10 to about 2000 ppm, preferably from about 30 to about 1500 ppm, more preferably from about 100 to about 1000 ppm. Any suitable surfactant may be employed. Among the suitable surfactant that may be employed in the highly aqueous, strongly basic, polysilicon planarizing solutions are any suitable water-soluble amphoteric, non-ionic, cationic or anionic surfactant.

Amphoteric surfactants useful in the highly aqueous, strongly basic, polysilicon planarizing solutions of the present invention include betaines and sulfobetaines such as alkyl betaines, amidoalkyl betaines, alkyl sulfobetaines and amidoalkyl sulfobetaines; aminocarboxylic acid derivatives such as amphoglycinates, amphopropionates, amphodiglycinates, and amphodipropionates; iminodiacids such as alkoxyalkyl iminodiacids or alkoxyalkyl iminodiacids; amine oxides such as alkyl amine oxides and alkylamido alkylamine oxides; fluoroalkyl sulfonates and fluorinated alkyl amphoterics; and mixtures thereof. Preferably, the amphoteric surfactants are cocoamidopropyl betaine, cocoamidopropyl dimethyl betaine, cocoamidopropyl hydroxy sultaine, capryloamphodipropionate, cocoamidodipropionate, cocoamphopropionate, cocoamphohydroxyethyl propionate, isodecyloxypropylimino dipropionic acid, laurylimino dipropionate, cocoamidopropylamine oxide and cocoamine oxide and fluorinated alkyl amphoterics.

Non-ionic surfactants useful in the highly aqueous, strongly basic, polysilicon planarizing solutions of the present invention include acetylenic diols, ethoxylated acetylenic diols, fluorinated alkyl alkoxylates, fluorinated alkylesters, fluorinated polyoxyethylene alkanols, aliphatic acid esters of polyhydric alcohols, polyoxyethylene monoalkyl ethers, polyoxyethylene diols, siloxane type surfactants, and alkylene glycol monoalkyl ethers. Preferably, the non-ionic surfactants are acetylenic diols or ethoxylated acetylenic diols. Especially useful is the acetylenic diol surfactant Surfynol 465.

Anionic surfactants useful in the highly aqueous, strongly basic, polysilicon planarizing solutions of the present invention include carboxylates, N-acylsarcosinates, sulfonates, sulfates, and mono and diesters of orthophosphoric acid such as decyl phosphate.

Cationic surfactants useful in the highly aqueous, strongly basic, polysilicon planarizing solutions of the present invention include amine ethoxylates, dialkyldimethylammonium salts, dialkylmorpholinium salts, alkylbenzyldimethylammonium salts, alkyltrimethylammonium salts, and alkylpyridinium salts.

The height of the polysilicon protrusions or projections extending upwardly from the generally planar polysilicon film will generally be in the range of from about 800 to about 1000 Å, although they may be somewhat less or somewhat more in height above the generally planar surface of the polysilicon film on the substrate. The planarizing solution of his invention is able to essentially or substantially eliminate these protrusion or projections without etching the generally planar polysilicon film layer.

The protrusions or projections rising from the surface of the generally planar polysilicon film on the substrate are essentially or substantially eliminated by contacting the surface of the general planar polysilicon film with the highly aqueous, strongly basic, polysilicon planarizing solutions of the present invention for a time and at a temperature sufficient to accomplish such selective removal of those protrusions or projections. Generally the contact time will be a period of from about 0.5 minutes to about 10 minutes, preferably for a period of from about 1 to about 6 minutes, more preferably from about 2 to about 3 minutes. The temperature of the process will be a temperature of from about 40° C. to about 80° C., preferably from about 55° C. to about 75° C., more preferably from about 60° C. to about 70° C. Most preferably the process is conducted for a period of about 2-3 minutes at a temperature of about 60-70° C. Temperature and time are variable constants because process condition can be varied by, parameters, including but not limited to: composition changes, LIPS panel status (depending on laser exposure energy, and aging time). The contacting of the protrusion or projection extending upwardly from the generally planar surface of the polysilicon film on a LTPS prepared panel can be by any suitable means, such as for example by dipping the panel in the planarizing solutions of this invention or by spraying the planarizing compositions of this invention onto the LIPS panels.

The invention is illustrated by the following illustrative, but non-limiting examples.

### EXAMPLES 1-6

LTPS panels having upwardly extending protrusion or projections having a height of from about 800 to about 1000 Å were each placed in a PTFA-coated panel basket/magazine, which was dipped in a bath filled with a LIPS Planarization Composition of this invention which Compositions had been heated to a temperature of about 65° to about 70° C. The bath had an impeller agitator and SUS-heater which made the temperature of bath be constant. After the designated time (in minutes) the panel basket/magazine was taken out of the Planarizing Composition and carried to a deionized water bath with fresh water overflow. Then each LIPS panel went through DI water rinse and drying with an air knife module. The same location of all the LIPS panel sample pieces were observed with FE SEM to determine the performance of new LIPS Planarization Compositions. The results are set forth in the following Table. In each case the LIPS Planarization Composition of the invention reduced or substantially eliminated the upwardly extending protrusions or projection on the LIPS panels without any significant etching of the generally planar polysilicon

TABLE

| | | | | | | | Planarization | | |
|---|---|---|---|---|---|---|---|---|---|
| | Poly-Si Planarization Composition | | | | | | Process | | |
| | | Etch | | | | | Conditions | | |
| Example | Strong | Control | | | LTPS Panel | | Temp. | Time | |
| No. | Base | Agent | Water | Oxidizer | Energy | Aging | ° C. | Min. | E/R (um/min) |
| 1 | 2.5% | 1% | 95.5% | 1.0% | 800 mJ | 1 day | 70 | 2 | 0.016 |
| 2 | 2.5% | 10% | 87.4% | 0% | 960 mJ | 1 day | 70 | 2.5 | 0.016 |
| 3 | 2.5% | 1% | 96.4% | 0.1% | 800 mJ | 1 day | 65 | 2 | 0.016 |
| 4 | 1.8% | 1% | 97.2% | 0.01% | 800 mJ | 1 week | 70 | 2.1 | 0.016 |
| 5 | 2.9% | 1% | 96.1% | 0% | 800 mJ | 1 week | 70 | 2 | 0.016 |
| 6 | 2.5% | 1% | 95.5% | 1.0% | 800 mJ | 2 weeks | 70 | 5 | 0.016 |

Base in Examples 1 to 3: Tetramethylammonium hydroxide
Base in Example 4: Tetramethylammonium hydroxide + Potassium Hydroxide (20:0.1)
Base in Example 5: Tetramethylammonium hydroxide + Potassium Hydroxide (30:0.1)
Base in Example 6: Tetramethylammonium hydroxide + Potassium Hydroxide (25:0.5)
Etch Control Agent in Examples 1 and 2: Triethylene glycol
Etch Control Agent in Example 3: Ethylene glycol
Etch control Agent in Example 4: Ethylene glycol ((0.1%) + Triethylene glycol (0.9%)
Etch Control Agent on Examples 5 and 6: Triethylene glycol (0.5%) + Surfynol 465 (0.5%)
Oxidizer in Examples 1, 3, 4 and 6: Ammonium persulfate

While the invention has been described herein with reference to the specific embodiments thereof, it will be appreciated that changes, modification and variations can be made without departing from the spirit and scope of the inventive concept disclosed herein. Accordingly, it is intended to embrace all such changes, modification and variations that fall with the spirit and scope of the appended claims.

1. A process for reducing or essentially eliminating protrusions or projections extending generally upwardly from a generally planar surface of polysilicon film produced by Low Temperature Poly Si (LIPS) annealing a film of amorphous silicon deposited on a substrate; the process comprising contacting the generally planar polysilicon film with a highly aqueous, strongly basic polysilicon planarizing solution for a time sufficient to selectively etch the protrusions or projections from the surface of the generally planar polysilicon film without any significant etching of the generally planar polysilicon film, said highly aqueous, strongly basic polysilicon planarizing solution comprising a solution having a pH of 12 or higher and comprising water, a least one strong base, and at least one etch rate control agent.

2. A process according to claim 1 wherein the at least one strong base of the polysilicon planarizing solution is selected from the group consisting of a tetraalkylammonium hydroxide, choline, an alkali hydroxide, an alkaline earth hydroxide, an alkali, alkaline earth or alkyl carbonate, an alkali, alkaline earth or alkyl acetate, an alkali, alkaline earth or alkyl alkoxide, an alkali, alkaline earth or alkyl cyanide, an alkali, alkaline earth or alkyl perchlorate, a mercapto compound, an alkyl phosphate, an alkyl arsenide, a Lewis base which can easily accept proton ions, and mixtures thereof.

3. A process according to claim 2 wherein the at least one strong base is selected from the group consisting of a tetraalkylammonium hydroxide, sodium hydroxide, potassium hydroxide and mixtures thereof.

4. A process according to claim 2 wherein the at least one etch control agent is selected from the group consisting of an alcohol and a glycol.

5. A process according to claim 4 wherein the at least one etch control agent is selected from the group consisting of ethylene glycol, glycerol, ethyl carbitol, triethylene glycol, tetraethylene glycol and mixtures thereof.

6. A process according to claim 4 wherein the polysilicon planarizing composition additionally contains a surfactant.

7. A process according to claim 6 wherein the surfactant is an acetylenic diol.

8. A process according to claim 2 wherein the polysilicon planarizing solution also has present at least one oxidizer.

9. A process according to claim 8 wherein the at least one oxidizer is selected from the group consisting of permanganates, perchromates, persulfates, perchlorates, peroxides, ozone and other hyper oxidized materials, and mixtures thereof.

10. A process according to claim 1 wherein the polysilicon planarizing solution contains at least one strong base selected from a tetraalkylammonium hydroxide, NaOH, KOH. And mixtures thereof, the at least one etch control agent is selected from ethylene glycol, glycerol and triethylene glycol and mixtures thereof, and the solution also has present at least one surfactant selected from acetylenic diols, and at least one oxidizer selected from persulfates.

11. A process according to claim 10 wherein the polysilicon planarizing solution has a pH of from about 13.2 to about 14.4, the at least one strong base is selected from the group consisting of tetramethylammonium hydroxide, KOH and mixtures thereof, the at least one etch control agent is selected from the group consisting of ethylene glycol, triethylene glycol and mixtures thereof, and the oxidizer is ammonium persulfate, with the strong base comprising about 0.1 to about 10% by weight, the etch control agent comprising about 0.1 to 10% by weight, the oxidizer about 0.05 to about 0.3% by weight, and the at least one surfactant comprises from about 10 to about 2000 ppm, the percentages being based on the total weight of the polysilicon planarizing solution.

12. A process according to claim 1 wherein the protrusion or projection extending upwardly from the surface of the generally planar polysilicon film extend upwardly to a height of from about 800 to about 1000 Å above the surface of the generally planar polysilicon film before the generally planar polysilicon film is contacted with the polysilicon planarizing solution.

13. A highly aqueous, strongly basis polysilicon planarizing solution capable of reducing or essentially eliminating protrusions or projections extending generally upwardly from a generally planar surface of polysilicon film produced by Low Temperature Poly Si (LIPS) annealing a film of amorphous silicon deposited on a substrate; the solution comprising water, at least one strong base, at least one etch control agent, and having a pH of 12 or higher.

14. A polysilicon planarizing solution according to claim 13 wherein the at least one strong base of the polysilicon planarizing solution is selected from the group consisting of a tetraalkylammonium hydroxide, choline, an alkali hydroxide, an alkaline earth hydroxide, an alkali, alkaline earth or alkyl carbonate, an alkali, alkaline earth or alkyl acetate, an alkali, alkaline earth or alkyl alkoxide, an alkali, alkaline earth or alkyl cyanide, an alkali, alkaline earth or alkyl perchlorate, a mercapto compound, an alkyl phosphate, an alkyl arsenide, a Lewis base which can easily accept proton ions, and mixtures thereof.

15. A polysilicon planarizing solution according to claim 14 wherein the at least one strong base is selected from the group consisting of a tetraalkylammonium hydroxide, sodium hydroxide, potassium hydroxide and mixtures thereof.

16. A polysilicon planarizing solution according to claim 14 wherein the at least one etch control agent is selected from the group consisting of an alcohol and a glycol.

17. A polysilicon planarizing solution according to claim 16 wherein the at least one etch control agent is selected from the group consisting of ethylene glycol, glycerol, ethyl carbitol, triethylene glycol, tetraethylene glycol and mixtures thereof.

18. A polysilicon planarizing solution according to claim 16 wherein the polysilicon planarizing composition additionally contains a surfactant.

19. A polysilicon planarizing solution according to claim 18 wherein the surfactant is an acetylenic diol.

20. A polysilicon planarizing solution according to claim 14 wherein the polysilicon planarizing solution also has present at least one oxidizer.

21. A polysilicon planarizing solution according to claim 20 wherein the at least one oxidizer is selected from the group consisting of permanganates, perchromates, persulfates, perchlorates, peroxides, ozone and other hyper oxidized materials, and mixtures thereof.

22. A polysilicon planarizing solution according to claim 13 wherein the polysilicon planarizing solution contains at least one strong base selected from the group consisting of a tetraalkylammonium hydroxide, NaOH, KOH and mixtures thereof, the at least one etch control agent is selected from the group consisting of ethylene glycol, glycerol and triethylene glycol and mixtures thereof, and the solution also has present at least one surfactant selected from acetylenic diols, and at least one oxidizer selected from persulfates.

23. A polysilicon planarizing solution according to claim 22 wherein the polysilicon planarizing solution has a pH of from about 13.2 to about 14.4, the at least one strong base is selected from the group consisting of tetramethylammonium hydroxide, KOH and mixtures thereof, the at least one etch control agent is selected from the group consisting of ethylene glycol, triethylene glycol and mixtures thereof, and the oxidizer is ammonium persulfate, with the strong base comprising about 0.1 to about 10% by weight, the etch control agent comprising about 0.1 to 10% by weight, the oxidizer about 0.05 to about 0.3% by weight, and the at least one surfactant comprises from about 10 to about 2000 ppm, the percentages being based on the total weight of the polysilicon planarizing solution.

24. A Low Temperature Poly Si (LIPS) coated substrate having a generally planar polysilicon film surface planarized by reducing or eliminating protrusion or projection upwardly extending from the film surface by the process according to any one of claims 1 to 12.
